(19) United States
(12) Patent Application Publication
(10) Pub. No.: US 2026/0206638 A1
(43) Pub. Date: Jul. 16, 2026

(54) CRYOGENIC-COMPATIBLE HERMETIC PACKING FOR SUPERCONDUCTING QUANTUM CHIPS

(71) Applicant: IQM FINLAND OY, Espoo (FI)

(72) Inventors: Jean-Luc ORGIAZZI, Espoo (FI); Olli-Pentti SAIRA, Espoo (FI)

(21) Appl. No.: 19/137,059

(22) PCT Filed: Dec. 11, 2023
(86) PCT No.: PCT/FI2023/050679

§ 371 Date: Jun. 9, 2025

(30) Foreign Application Priority Data
Dec. 9, 2022 (FI) 20227161

(51) Int. Cl. H10W 76/18; H10W 40/30; H10W 42/20; H10W 70/692; H10W 76/60; H10W 90/28

(52) U.S. Cl. CPC H10W 76/18; H10W 40/305; H10W 42/281; H10W 70/692; H10W 76/60; H10W 90/28

(57) ABSTRACT

The invention relates to a packaging structure for a superconducting quantum processing unit. The packaging structure comprises a ceramic support portion for supporting a quantum processing unit, the support portion including a plurality of electrical connections for connecting the quantum processing unit to a plurality of electrical contacts on an exterior surface of the ceramic packing structure. The invention also relates to a packaged quantum processing unit and method for packaging a quantum processing unit using the above packaging structure.

### TECHNICAL FIELD

The invention in generally related to material science. In particular, the invention is related to ceramic based materials suitable for various solutions in cryogenic environments and superconducting applications, such as quantum information processing and quantum hardware.

### BACKGROUND

The heart of a superconducting QPU is a silicon or sapphire chip, with qubit structures made of superconducting metal on top of it. In a large QPU, the qubits will be arranged in a two-dimensional lattice. To route control signals into the middle of the lattice, wires need to be brought in from a direction perpendicular to the plane.

The wiring solution needs to simultaneously meet several criteria, which include: high bandwidth (for some signals), controlled impedance, low cross-talk, low dissipation, low microwave loss, shielding of qubit circuits from lossy materials, tight pitch compatible with the dimensions of the QPU unit cell and number of signals per unit cell, high reliability, and the ability to replace the QPU.

Ceramic technology as a packaging solution for semiconductor dies in general is well known, for example in solutions using a silicon substrate and multi-layer wiring using planarized dielectric material.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter. It is an objective to provide a novel material comprising ceramic and a metal component that provides superconducting properties into the functional ceramic substrate. The material can be manufactured with known manufacturing methods, e.g. by utilizing low temperature co-fired ceramics (LTCC) base or green sheets or other substrates to which a mixture of suitable metal and e.g. a polymer carrier is deposited as a layer and then prefired or dried; functionalized layers developed as needed on top of the prefired green sheets, including for example physical two-dimensional or three-dimensional structures such as trough-vias, cavities, routes etc and finally pressed and fired so as to achieve a functionalized multilayer structures that can be utilized as components for several different purposes as disclosed in the following. This kind of material has many beneficial properties including high stiffness, conductivity properties, thermal expansion coefficient suitable for various applications, impermeability to gases (because of the glass-like composition after firing) and machineability, to mention a few. It can also be readily used as a base layer or interposer layer for various purposes.

The solution meets all the engineering criteria disclosed in the Background section, while being relatively cheap and scalable to large substrate sizes (up to 6″ or 15,24 cm) and a large number of wiring layers (up to 38 layers) using readily available processes. It should be noted that the compressible springs require a significant amount of force (typ. 10 grams per contact) and the ceramic layer is needed to avoid extensive bowing of the chip stack, which would compromise the usability of the QPUs and the superconducting chips.

The problem(s) the invention solves include:
vertical delivery of signals and fan-out of signals from dense pitch silicon TSV pads array to traditional PCBs
proposing a material with CTE closer to silicon than traditional PCBs
higher signal to signal isolation than SiO2/Si multilayer wiring
stiffness of rigid ceramic stack might allow the use of compressible spring contacts for reusable packages and easy sample swap, enabling high throughput good-sample discovery.

The proposed technical solutions and possible alternatives include a ceramic based multilayer (30~50 layers possible) interposer with Indium-based solder contacts or spring contacts.

Thus, a first aspect of the invention relates to a packaging structure for a superconducting quantum processing unit. The packaging structure comprises a ceramic support portion for supporting a quantum processing unit, the support portion including a plurality of electrical connections for connecting the quantum processing unit to a plurality of electrical contacts on an exterior surface of the ceramic packing structure.

A second aspect of the invention relates to a packaged quantum processing unit comprising the packaging structure and a quantum processing unit.

The packaging structure may further comprise one or more sidewalls enclosing the plurality of electrical connections in at least two dimensions, and the space enclosed by the one or more sidewalls may be configured to house the quantum processing unit. The one or more sidewalls may be formed of a ceramic material.

The packaging structure may further comprises a lid configured to enclose the plurality of electrical connections such that the support portion, one or more sidewalls and lid form a cavity configured to house the quantum processing unit and enclosed in three-dimensions. The lid may also be formed of a ceramic material. Alternatively, the lid may be formed of metallic material.

One or more of the support portion, sidewalls and lid may be formed of a ceramic material comprising one or more layers or traces of superconducting material within or on the surface of the ceramic material. Thus, the ceramic material may comprise a layer of superconducting metal. The ceramic material may be a low temperature co-fired ceramic or a high-temperature co-fired ceramic.

The ceramic material comprising one or more layers or traces of superconducting material may shield the cavity from external electric and magnetic fields.

The packaging structure may further comprise one or more of activated carbon, a getter, and a molecular sieve.

The plurality of electrical connections of the support portion may extend over at least 50 mm in one direction.

The coefficient of thermal expansion of the ceramic support portion may be within ±50% of the coefficient of thermal expansion of silicon at 1K and 300K.

The cavity may be hermetically sealed. The cavity may be under vacuum or filled with an inert gas.

The inert gas may be helium configured to form a superfluid when the packaged quantum processing unit is cooled to cryogenic temperatures.

A third aspect of the invention relates to a method of manufacturing a packaged quantum processing unit. The method comprising inserting a quantum processing unit into a packaging structure, the packaging structure comprising a ceramic support portion for supporting the quantum processing unit, and connecting the quantum processing unit to a plurality of electrical connections located on the support portion, the electrical connections configured to connecting the quantum processing unit to a plurality of electrical contacts on an exterior surface of the ceramic packing structure.

Tthe packing structure may further comprise one or more sidewalls enclosing the plurality of electrical connections in at least two dimensions, and the space enclosed by the one or more sidewalls is configured to house the quantum processing unit.

The method may further comprise enclosing the quantum processing unit in the packaging structure by sealing the enclosed space with a lid.

The lid and one or more sidewalls may form a hermetic seal around the quantum processing unit. Enclosing the quantum processing unit may be performed in a vacuum or inert gas environment, e.g. helium.

### BRIEF DESCRIPTION OF THE DRAWINGS

FIG. 1 depicts a conventional manufacturing method for ceramic functional layer.

FIG. 2 depicts a schematic QPU or chip stack with an interposer layer made of the superconducting material.

FIG. 3 depicts a packaging structure for a superconducting quantum processing unit.

FIG. 4 depicts a cross-section of the packaging structure of FIG. 3.

FIG. 5 depicts the underside of the packaging structure of FIG. 3.

FIG. 6 depicts a method of packaging a superconducting quantum processing unit.

### DETAILED DESCRIPTION

The invention comprises a general idea of utilizing a ceramic material as a component in a chip such as a superconducting chip comprising at least one QPU, similar to a conventional semiconductor chip on a printed circuit board. Since the ceramic material can be made superconducting as described above, it is particularly suitable for superconductors, for example in quantum computers with quantum processing units, QPUs. In this context, “superconducting ceramic” means a ceramic material with one or more layers or traces of superconducting material within or on the surface of the ceramic material.

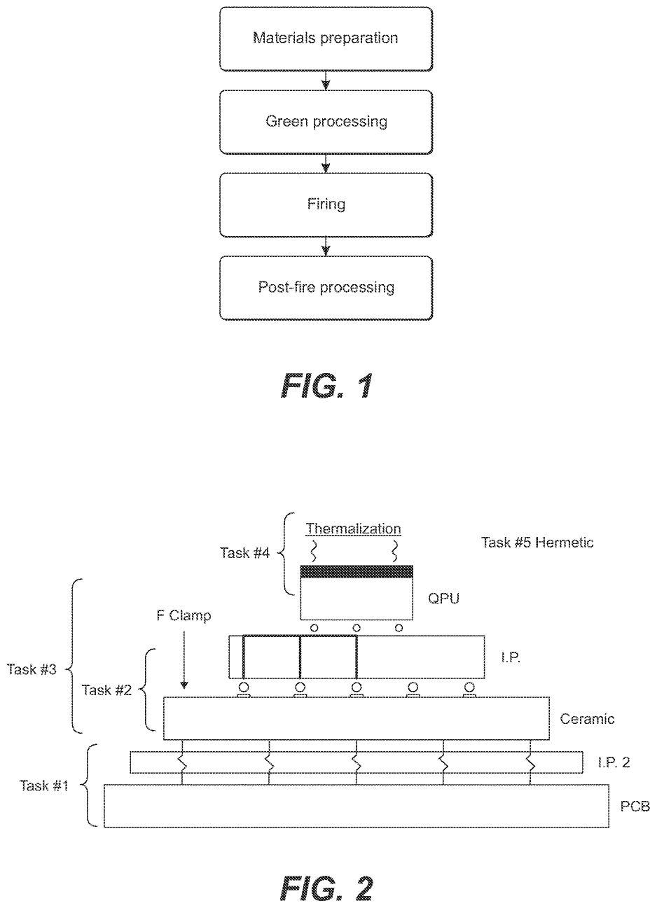

In essence the ceramic material can be made superconducting by including a suitable superconducting (metal) material into its composition, for example by introducing a superconducting material into a slurry coating a LTCC green base material or sheet and manufacturing ceramic multilayer structures from that via conventional manufacturing methods as known in the field (see FIG. 1), e.g. introducing the metal material onto a green sheet in a slurry with a suitable binding component, such as polymer and firing the resulting composition to provide a single body of superconducting ceramic material. This superconducting material could, for example, be aluminium-based, or comprise niobium, molybdenum or tungsten. Especially the last two may be suitable due to their high melting point. A ceramic material of such a composition or even with a suitable metal layer provides a low-loss routing structure within a chip layer made of this material, such as an interposer layer in a stack of chips. The superconducting ceramic material is amorphous and has virtually no resonance. As an alternative to LTCCs, high-temperature co-fired ceramics (HTCCs) may be used, along with tungsten, molybdenum, niobium (e.g. niobium nitride), and/or titanium (e.g. titanium nitride) based metal pastes or slurries.

The resulting superconducting ceramic material can be freely modified e.g. by machining it into desired shapes or structures having cavities, routing channels (either vertical or lateral), inlays or any other suitable structures in, on or through the material layer.

In an embodiment niobium-based superconducting ceramic material is used for various superconducting applications. It is for example fully compatible for any currently known flip-chip construction, and many more can be envisioned. Aluminium nitrate is also a possible superconducting component that could be used. A printed circuit board made of the superconducting ceramic material according to the invention could be used as a base layer for a superconducting chip stack comprising a large number of qubits on the QPU layer as relatively large PCBs could be manufactured because of the stiffness of the ceramic material. It could be possible to manufacture QPU stacks comprising>1000 qubits this way.

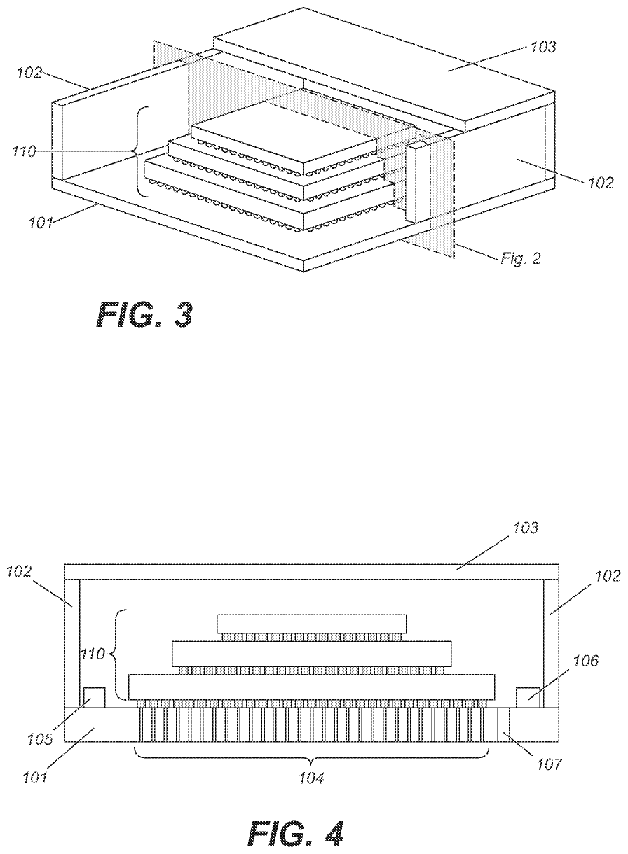

The ceramic material can be used as interposer layer(s) in a superconducting QPU stack (see FIG. 2), to provide structural integrity to a stack comprising a QPU and a dielectric insulation layer on top of a printed circuit board (PCB). The control lines delivering signals and needed electrical components can be embedded or brought through the ceramic interposer layer(s) bonded to the QPU chip layer by for example indium bumps, as is known from flip-chip type of QPUs according to state of art. A number of electronic lines can be brought through the ceramic interposer layer according to the invention by using so-called through-vias similarly to common silicon chip layers where trough-silicon-vias are utilized for this purpose, without compromising the structural integrity of the ceramic interposer layer. Thereafter, the stack of different layers can be pressed together to form a stacked superconductor element or chip by pressing on the ceramic interposer layer instead of the fragile QPU or flip-chip layer. On the PCT, ardent connectors or equivalent can be used to direct the control lines outside the chip stack. It is thus possible to align and press the stack together to connect with the ardent connector pins without breaking the structurally fragile parts or layers of the stack. The ceramic interposer layer can also be used to deliver signals via lines embedded in the lateral direction of the interposer layer. In essence the ceramic interposer layer may thus be a functional structure rather than a mechanical structure.

Alternatively or additionally, the chip stack is a wiring stack that has spring contact pins (‘pogo pins’ or ‘fuzz buttons’) at one interface in the stack, and indium or low-temperature solder contacts at another interface in the stack, and the ceramic layer is used to route electrical signals between the two interfaces.

A stack of interposers as shown in FIG. 2. The components from top to bottom are. 1) QPU chip (“QPU” in sketch). 2) First Interposer (“I.P.”) that is a Silicon chip with thru-silicon via's, with superconducting patterned metallization on both faces. 3) A ceramic wiring layer (“Ceramic”). 4) A second interposer (“I.P2”) 5) A traditional printed circuit board (“PCB”). The electrical contacts at the QPU-I.P. and the Ceramic-I.P. interface are realized as indium or low-temperature solder balls or bumps. The electrical contacts between the Ceramic and the PCB layers are realized as compressible springs embedded in IP2. The ceramic layer is pressed down (with force F clamp) by a torus-shaped clamp that is not shown.

Many variants are possible. The PCB layer could be replaced with a block into which coaxial wires terminate (similar to an Ardent TR interface). The compressible springs could be regular solder joints.

The superconducting ceramic material may also be utilized in ceramic-based high-density microwave connector applications, for example for directing signals from room-temperature environment to a cryostat or between the different temperature zones of a cryostat.

The superconducting ceramic material enables reducing the dimensions of the connector significantly. For example, in a connector dimensionally equivalent to an ardent connector, hundreds of lines could be implemented instead of the 24 of an ardent connector. In FIG. 4, an exemplary construction of such a connector according to the invention is presented. It comprises machining the superconducting ceramic material described above into a suitable shape and size to allow use with different multiwire connector solutions. In one specific embodiment, nanoscale or picoscale coaxial cables available to be purchased commercially are used to realize the connection of signal lines to the connector. Such cables could be arranged into a 50×50 or 100×100 lateral construction, cables realizing signal lines to and from the different temperature zones of a cryostat all the way to the QPU, and alternatively or additionally, to and from the cryostat to the room temperature environment. This would significantly reduce the space taken up by wiring and cabling, and also reduce the thermal load from the signal lines.

The above-described connector could be used as a cryogenic alternator between the different temperature zones of a cryostat, enabling efficient delivery of signals through electrical lines realized through the superconducting ceramic material based connectors.

The superconducting ceramic material may also be utilized in feed-through vacuum hermetic connectors, or ultra-high vacuum coaxial high-density microwave feed-throughs feeding control signals in and out of the cryostat.

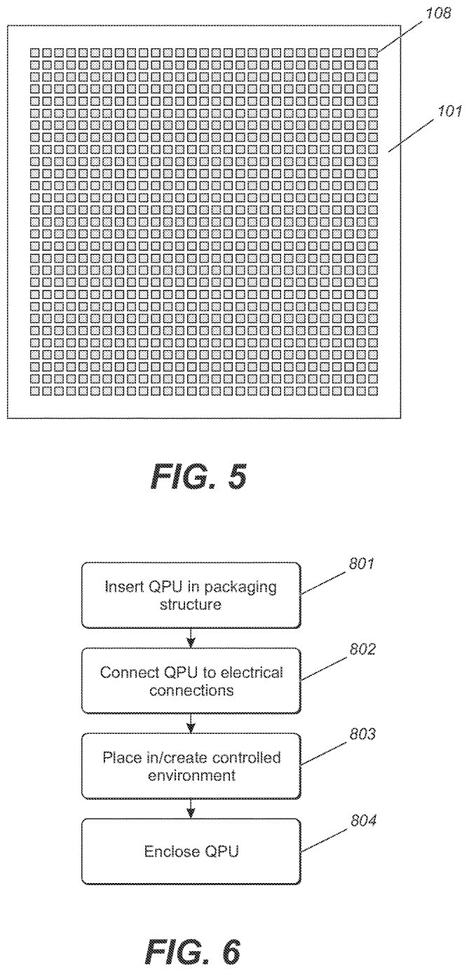

As depicted in FIGS. 5 to 7, the superconducting ceramic material may also be utilized in vacuum environmentally controlled packaging of QPUs. For example, a suitable gas can be introduced into the cavity around a QPU to prevent oxidation and degradation of the QPU structure over time.

In FIG. 3, such a package is presented in an exemplary manner. FIG. 4 is a cross-section of the package shown in FIG. 3. FIG. 5 shows the underside of the package of FIGS. 5 and 6. The package 101 includes a support portion (base layer) 101 machined to create a suitable cavity for the QPU 110 together with a lid (top layer) 103, and channels 104 coated in or filled with metal for control lines to control the environment inside the QPU cavity. The channels 104 are connected to electrical contacts 108 (shown in FIG. 5) on an exterior surface of the package and form electrical (and optionally thermal) connections between the exterior and interior of the package 100.

The QPU cavity is further defined by one or more sidewalls 102, which enclose the electrical connections/channels 104 in at least two dimensions, that is, if the surface of the support portion 101 on which the QPU 110 is supported defines an X-Y plane, the side walls enclose the cavity in the X and Y dimensions at least. The lid 103 encloses the cavity in the Z-direction. Where the lid 103 and one or more sidewalls are integrally formed, it could be said that the cavity is also be enclosed in the Z dimension by the sidewall(s).

The space enclosed by the sidewalls 102 and lid 103, i.e. the cavity, is configured to house the QPU 110. The sidewalls 102, lid 103, and support portion 101 may form a hermetic seal around the cavity suitable for creating and supporting a vacuum. In this context, a hermetic seal may be defined as a seal having a leak rate of at most 1×10⁻⁸ cc/s according to MIL-STD-750E test method 1071.9 or MIL-STD-883H test method 1014.13.

The sidewalls 102 and/or lid 103 may also be formed of the superconducting ceramic material described above with respect to FIG. 1. Where the ceramic material is a superconducting ceramic material, the package 100 may therefore provide an almost completely isolated electromagnetic environment within the cavity. Alternatively, the sidewalls 102 and/or lid 103 may be formed of a metallic material, which may form a Faraday shield around the cavity even if the metallic material is not superconducting for blocking high-frequency electromagnetic fields.

The cavity may also be connectable to an ion pump, cryopump or other vacuum pump. For creating and/or maintaining a vacuum within the cavity. As such, a suitable channel 107 connecting the cavity to the vacuum pump is provided in either the support portion 101 (as depicted in FIG. 4) or in the sidewalls(s) 102 or lid 103. Alternatively or additionally, a vacuum may be created within the cavity of the package 100 prior to sealing the cavity with the lid 103.

Alternatively, the cavity may be filled with an inert gas. The use of an inert gas within the cavity may allow for greater heat dissipation from the QPU and more uniform heat distribution within the cavity. In one example, the inert gas may be helium. The helium within the cavity forms a superfluid under the cryogenic conditions at which the QPU is operated. As a superfluid, the helium within the cavity coats the QPU and the interior walls of the cavity, allowing for superior heat distribution and dissipation out of the cavity.

The package 100 may include sorption elements 105, 106 such as one or more of: an adsorbent element (e.g. activated charcoal, zeolite), absorbent element (e.g. palladium or palladium composite), and a molecular sieve for adsorbing harmful substances smaller than a particular molecule size. In this context, a “harmful” substance is one whose presence within the package leads to reduced performance of the QPU, e.g. due to degraded qubit decoherence times. In addition, the control lines can be used to homogenize the temperature within the package. The use of one or more sorption elements 105, 106 within the packages also enables a vacuum within the cavity to be maintained for longer periods of time despite the inevitable infiltration of the cavity by small molecules.

The package 100 may also be used without sidewalls 102 or lid 103 as a tool for high-throughput testing of QPUs. In particular, the physical properties of the ceramic support portion 101 enable clamps, such as F-clamps shown in FIG. 2, to be used to exert significant force on the support portion (labelled “Ceramic”) and compress temporary connectors, such as fuzz buttons, arranged in a land grid array on “I.P. 2”, against the electrical connections on the underside of the support portion 101. This is not possible with conventional silicon substrates as the forces required to compress large numbers, e.g. hundreds, of these temporary connections to form reliable electrical connections would cause the silicon to shatter. Thus, the use of the ceramic material for the support portion 101 enables QPUs located on the support portion 101 to be quickly and easily inserted and removed from a testing environment.

The package 100 of the present invention is particularly effective at minimising degradation of the QPU and the sensitive components that make it up, such as Josephson junction. When the QPU is exposed to moisture, and atmospheric gases, as well as repeated thermal cycling, the performance of the QPU, such as qubit coherence times, degrades. The package 100 protects the QPU from the main sources of contamination, i.e. hydrogen, oxygen and moisture. Furthermore, many ceramic materials have coefficient of thermal expansion (CTE) in the relevant temperature range, i.e. 0 to 300K, that is close to that of silicon, a common substrate used for superconducting quantum processing units. This is important for large enclosures and large QPUs, e.g. those with connections between the QPU and package support portion 101 spanning at least 50 mm in at least one dimension, since the relative movement of contacts on the QPU and corresponding contacts on the support portion 101 under thermal cycling, i.e. change of temperature from room temperature to cryogenic temperatures, increases as the size of the QPU increases. Large relative movement of the QPU and support portion leads to degradation and ultimately breakage of the electrical connections between the QPU and support portion. In this context, “closely matched” CTE means that the CTE of the ceramic material is ±50% of the CTE of silicon at 1K and 300K.

The invention also includes a method of manufacturing a packaged quantum processing unit. The method 200 is depicted in FIG. 6.

At step 801, a quantum processing unit is inserted in a packaging structure that includes a ceramic support portion for supporting the quantum processing unit, for example as described above with respect to FIGS. 5 to 7.

At step 802, the quantum processing unit is connected to a plurality of electrical connections located on the support portion, e.g. electrical connections 104 shown in FIGS. 5 to 7. The electrical connections are configured to connecting the quantum processing unit to a plurality of electrical contacts on an exterior surface of the ceramic packing structure, e.g. the electrical contacts 107 shown in FIG. 5.

As described above with respect to FIGS. 5 to 7, the packing structure may include one or more sidewalls that enclose the electrical connections in at least two dimensions. The space enclosed by the one or more sidewalls is configured to house the quantum processing unit.

At step 803, the quantum processing unit and open packaging structure are placed in a controlled environment, e.g. an inert gas environment or vacuum.

At step 804, the quantum processing unit is enclosed in the packaging structure by sealing the enclosed space with a lid. The lid and one or more sidewalls may form a hermetic seal around the quantum processing unit. Carrying out this step in the controlled environment ensures that the cavity enclosed by the sidewalls and lid is filled with an inert gas, such as helium, or is under vacuum.

1. A packaging structure for a superconducting quantum processing unit, the packaging structure comprising:
a ceramic support portion for supporting a quantum processing unit, the support portion including a plurality of electrical connections for connecting the quantum processing unit to a plurality of electrical contacts on an exterior surface of the ceramic support portion.

2. A packaged quantum processing unit comprising the packaging structure of claim 1 and a quantum processing unit.

3. The packaging structure of claim 1, wherein the packaging structure further comprises one or more sidewalls enclosing the plurality of electrical connections in at least two dimensions, wherein the space enclosed by the one or more sidewalls is configured to house the quantum processing unit.

4. The packaging structure of claim 3, wherein the one or more sidewalls are formed of a ceramic material.

5. The packaging structure of claim 3, wherein the packaging structure further comprises a lid configured to enclose the plurality of electrical connections such that the support portion, one or more sidewalls and lid form a cavity configured to house the quantum processing unit and enclosed in three-dimensions.

6. The packaging structure of claim 5, wherein the lid is formed of a ceramic material and/or metallic material.

7. The packaging structure of claim 6, wherein one or more of the support portion, sidewalls and lid are formed of a ceramic material comprising one or more layers or traces of superconducting material within or on the surface of the ceramic material.

8. The packaging structure of claim 7, wherein the ceramic material comprises a layer of superconducting metal.

9. The packaging structure of claim 8, wherein the ceramic material is a low temperature co-fired ceramic or a high-temperature co-fired ceramic.

10. The packaging structure of claim 9, wherein the ceramic material shields the cavity from external electric and magnetic fields.

11. The packaging structure of claim 1, wherein the packaging structure further comprises one or more of activated carbon, a getter, and a molecular sieve.

12. The packaging structure of claim 1, wherein the plurality of electrical connections of the support portion extends over at least 50 mm in one direction.

13. The packaging structure of claim 1, wherein the coefficient of thermal expansion of the ceramic support portion is within ±50% of the coefficient of thermal expansion of silicon at 1K and 300K.

14. The packaging structure of claim 5, wherein the cavity is hermetically sealed.

15. The packaging structure of claim 14, wherein the cavity is under vacuum.

16. The packaging structure of claim 15, wherein the cavity is filled with an inert gas.

17. The packaging structure of claim 16, wherein the inert gas is helium, and wherein the helium is configured to form a superfluid when the packaged quantum processing unit is cooled to cryogenic temperatures.

18. A method of manufacturing a packaged quantum processing unit, the method comprising:
inserting a quantum processing unit into a packaging structure, the packaging structure comprising a ceramic support portion for supporting the quantum processing unit;
connecting the quantum processing unit to a plurality of electrical connections located on the support portion, the electrical connections configured to connecting the quantum processing unit to a plurality of electrical contacts on an exterior surface of the ceramic support portion.

19. The method of claim 18, wherein the packing structure further comprises one or more sidewalls enclosing the plurality of electrical connections in at least two dimensions, wherein the space enclosed by the one or more sidewalls is configured to house the quantum processing unit.

20. The method of claim 19, wherein the method further comprises enclosing the quantum processing unit in the packaging structure by sealing the enclosed space with a lid, wherein the lid and one or more sidewalls form a hermetic seal around the quantum processing unit, wherein enclosing the quantum processing unit is performed in a vacuum or inert gas environment, wherein the inert gas is helium.

21. (canceled)

22. (canceled)

23. (canceled)
